(19) United States
(12) Patent Application Publication
(10) Pub. No.: US 2014/0268622 A1
(43) Pub. Date: Sep. 18, 2014

(54) FIXING MECHANISM FOR FIXING AN PORTABLE ELECTRONIC DEVICE AND RELATED ELECTRONIC APPARATUS

(71) Applicant: Wistron Corporation, New Taipei City (TW)

(72) Inventor: Yi-Hsiang Chao, New Taipei City (TW)

(73) Assignee: Wistron Corporation, New Taipei City (TW)

(21) Appl. No.: 14/072,792

(22) Filed: Nov. 6, 2013

(30) Foreign Application Priority Data
Mar. 14, 2013 (TW) 102109085

(51) Int. Cl. H05K 5/02

(52) U.S. Cl. CPC H05K 5/0217
USPC 361/809; 248/316.7; 248/309.4

(57) ABSTRACT

The present invention discloses a fixing mechanism including a base, a cover, a connecting component, at least one resilient component and a pushing component. The base is for containing a portable electronic device. The cover is pivoted to the base. The connecting component is disposed on the base for engaging with the cover. The at least one resilient component is disposed on the base. The pushing component is connected to the at least one resilient component and the connecting component, the pushing component is driven to move in a first direction as the portable electronic device is installed on the base, so as to drive the connecting component to separate from the cover, so that the cover pivots in a first pivoting direction relative to the base to engage with the end of the portable electronic device.

### BACKGROUND OF THE INVENTION

1. Field of the Invention

The present invention relates to a fixing mechanism for fixing a portable electronic device and a related electronic apparatus, and more specifically, to a fixing mechanism for fixing a portable electronic device by one hand and a related electronic apparatus.

2. Description of the Prior Art

In modern society, a smart phone has become the most popular portable electronic device. A user can utilize various functions of the smart phone anytime and anywhere, such as browsing websites, listening to the music, and so on. In addition, because the smart phone is applied widely, the user often uses the smart phone to listen to the music or to navigate as driving. The smart phone is usually installed inside a vehicle by a fixing mechanism, such as a supporting frame, so as to facilitate the user to operate the smart phone. However, a mechanical design of the conventional supporting frame does not facilitate the user to install the smart phone. That is, the user has to install the smart phone on the supporting frame or detach the smart phone from the supporting frame by both hands, resulting in inconvenience of operation. Moreover, installing or detaching the smart phone as driving may affect driving safety. Therefore, it is an important issue to design a fixing mechanism for installing or detaching the smart phone easily.

### SUMMARY OF THE INVENTION

The present invention is to provide a fixing mechanism for fixing a portable electronic device by one hand and a related electronic apparatus, to solve the above problems.

According to the disclosure, a fixing mechanism includes abase, a cover, a connecting component, at least one resilient component and a pushing component. The base is for containing the portable electronic device. The cover is pivoted to the base, a first engaging unit is formed on the cover, and the cover is for engaging with an end of the portable electronic device after the cover pivots relative to the base in a first pivoting direction, so as to fix the portable electronic device on the base. The connecting component is disposed on the base, and the connecting component includes a second engaging unit for engaging with the first engaging unit of the cover. The at least one resilient component disposed on the base. The pushing component is connected to the at least one resilient component and the connecting component. The pushing component is driven to move in a first direction as the portable electronic device is to be installed on the base, so as to drive the connecting component to separate from the first engaging unit of the cover, so that the cover pivots in the first pivoting direction relative to the base to engage with the end of the portable electronic device.

According to the disclosure, the first engaging unit is a slot structure.

According to the disclosure, the connecting component is disposed on an outer side of the base, and the at least one resilient component is disposed on an inner side of the base.

According to the disclosure, after the portable electronic device is fixed on the base and the cover is forced to pivot in a second pivoting direction opposite to the first pivoting direction relative to the base, the cover is separated from the end of the portable electronic device, and the at least one resilient component drives the pushing component to push the portable electronic device, so that the portable electronic device is separated from the base.

According to the disclosure, a protruding portion is formed on the cover for being forced to pivot the cover in the second pivoting direction.

According to the disclosure, a constraining portion is further formed on the cover, a supporting portion is formed on the base, and the constraining portion and the supporting portion are for holding the portable electronic device cooperatively.

According to the disclosure, the fixing mechanism further includes at least one pivoting shaft and at least one recovering component. The at least one pivoting shaft is for pivoting the cover with the base. The at least one recovering component is installed on the at least one pivoting shaft, and the at least one recovering component is for driving the cover to pivot in the first pivoting direction as the connecting component is separated from the first engaging unit of the cover, so that the cover is engaged with the end of the portable electronic device.

According to the disclosure, the fixing mechanism further includes a first connector and a first magnetic component. The first connector is disposed on the base for connecting with a second connector of the portable electronic device. The first magnetic component is disposed on the base for attracting an attracting component of the portable electronic device, so as to prevent the portable electronic device from separating from the base.

According to the disclosure, the fixing mechanism further includes a second magnetic component disposed on the base for attracting the attracting component of the portable electronic device with the first magnetic component cooperatively, so as to prevent the portable electronic device from separating from the base.

According to the disclosure, the second engaging unit is a cylindrical engaging portion for engaging with the first engaging unit of the cover.

According to the disclosure, an electronic apparatus includes a portable electronic device and a fixing mechanism fixing the portable electronic device. The fixing mechanism includes a base, a cover, a connecting component, at least one resilient component and a pushing component. The base is for containing the portable electronic device. The cover is pivoted to the base, a first engaging unit is formed on the cover, and the cover is for engaging with an end of the portable electronic device after the cover pivots relative to the base in a first pivoting direction, so as to fix the portable electronic device on the base. The connecting component is disposed on the base, and the connecting component includes a second engaging unit for engaging with the first engaging unit of the cover. The at least one resilient component disposed on the base. The pushing component is connected to the at least one resilient component and the connecting component. The pushing component is driven to move in a first direction as the portable electronic device is to be installed on the base, so as to drive the connecting component to separate from the first engaging unit of the cover, so that the cover pivots in the first pivoting direction relative to the base to engage with the end of the portable electronic device.

According to the disclosure, the electronic apparatus further includes a power transmission component connected to the first connector, and the power transmission component is for transmitting external power to the portable electronic device which is connected to the first connector.

According to the disclosure, the electronic apparatus further includes a stand and a connection component. The stand is for fixing the fixing mechanism inside a vehicle. The connection component is fixed outside the base and for connecting the stand.

The fixing mechanism 58 of the present invention is to dispose the cover capable of pivoting relative to the base, the connecting component engaged with the cover and the pushing component connected to the connecting component, so that the pushing component is pushed in the first direction as the portable electronic device is to installed on the base, so as to drive the connecting component to separate from the first engaging unit of the cover. At this time, the cover can pivot relative to the base to engage with the portable electronic device, so as to fix the portable electronic device on the fixing mechanism by one hand. Therefore, it solves the conventional problem that it has to install the portable electronic device on the conventional fixing mechanism by both hands in the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of an electronic apparatus according to an embodiment of the present invention.

FIG. 2 is a diagram of a fixing mechanism connecting with the stand 54 according to the embodiment of the present invention.

FIG. 3 is another view of the fixing mechanism connecting with the stand 54 according to the embodiment of the present invention.

FIG. 4 is a sectional view illustrating that a portable electronic device has not been installed on the fixing mechanism according to the embodiment of the present invention.

FIG. 5 is a sectional view illustrating that the portable electronic device has been installed on the fixing mechanism according to the embodiment of the present invention.

FIG. 6 is a sectional view illustrating that the portable electronic device is separated from the fixing mechanism according to the embodiment of the present invention.

### DETAILED DESCRIPTION

Please refer to FIG. 1. FIG. 1 is an exploded diagram of an electronic apparatus 52 according to an embodiment of the present invention. The electronic apparatus 52 of the present invention includes a stand 54, a portable electronic device 56 and a fixing mechanism 58. The portable electronic device 56 can be a smart phone or a vehicle navigator. The stand 54 is for fixing the fixing mechanism 58 inside a vehicle. For example, the stand 54 can attach the fixing mechanism 58 on a windshield of the vehicle. The fixing mechanism 58 is for fixing the portable electronic device 56 and is suitable for the portable electronic device 56 with different sizes. That is, a thick or a slim portable electronic device 56 can be fixed on the fixing mechanism 58. Please refer to FIG. 1 to FIG. 3. FIG. 2 is a diagram of the fixing mechanism 58 connecting with the stand 54 according to the embodiment of the present invention. FIG. 3 is another view of the fixing mechanism 58 connecting with the stand 54 according to the embodiment of the present invention. The fixing mechanism 58 includes a base 60, a cover 62, a connecting component 64, at least one resilient component 66 and a pushing component 68. The base 60 is for containing the portable electronic device 56, so that the portable electronic device 56 can be fixed on the fixing mechanism 58 stably. In addition, the fixing mechanism 58 further includes at least one pivoting shaft 70 for pivoting the cover 62 with the base 60. That is, the cover 62 is pivoted to the base 60 via the at least one pivoting shaft 70. In this embodiment, the fixing mechanism 58 includes two pivoting shafts 70, but is not limited to it.

Moreover, a first engaging unit 621 is formed on the cover 62, and the first engaging unit 621 can be a slot structure. The cover 62 is for engaging with an end of the portable electronic device 56 after the cover 62 pivots relative to the base 60 in a first pivoting direction R1, so as to fix the portable electronic device 56 on the base 60. At least one constraining portion 623 can be further formed on the cover 62, and at least one supporting portion 601 can be formed on the base 60. The at least one constraining portion 623 and the at least one supporting portion 601 are for holding the portable electronic device 56 cooperatively. In this embodiment, two constraining portions 623 are formed on the cover 62, and two supporting portions 601 can be formed on the base 60. As the portable electronic device 56 is installed on the base 60, and the cover 62 pivots to the end of the portable electronic device 56 in the first pivoting direction R1, the two supporting portions 601 constrain the other end other portable electronic device 56, so that the two constraining portions 623 and the two supporting portions 601 can constrain the degree of freedom in every direction.

The connecting component 64 is disposed on an outer side of the base 60 for engaging with the first engaging unit 621 of the cover 62. The connecting component 64 includes a second engaging unit 641 for engaging with the first engaging unit 621 of the cover 62. In this embodiment, the second engaging unit 641 can be a cylindrical engaging portion, and the first engaging unit 621 can be the slot structure accordingly. The cylindrical engaging portion can be engaged with the slot structure. An engaging mechanism of the first engaging unit 621 and the second engaging unit 641 is not limited to this embodiment. All engaging mechanisms for preventing the cover 62 from pivoting in the first pivoting direction R1 by engagement of the first engaging unit 621 and the second engaging unit 641 are within the scope of the present invention. The at least one resilient component 66 is disposed on an inner side of the base 60. In this embodiment, the fixing mechanism 58 can include two resilient components 66, and each resilient component 66 can be a spring.

In addition, the fixing mechanism 58 further includes at least one recovering component 72 installed on the corresponding pivoting shaft 70. The recovering component 72 is for driving the cover 62 to pivot in the first pivoting direction R1 as the connecting component 64 is separated from the first engaging unit 621 of the cover 62, so that the cover 62 is engaged with the end of the portable electronic device 56. In this embodiment, the fixing mechanism 58 includes two recovering components 72, and each recovering component 72 can be a torsion spring. The pushing component 68 is connected to the at least one resilient component 66 and the connecting component 64. In this embodiment, the pushing component 68 passes through the at least one resilient component 66. The pushing component 68 is driven to move in a first direction (+X direction) as the portable electronic device 56 is to be installed on the base 60, so as to drive the connecting component 64 to separate from the first engaging unit 621 of the cover 62. At this time, the cover 62 is not constrained by the connecting component 64, so that the recovering component 72 can drive the cover 62 to pivot in the first pivoting direction R1 relative to the base 60 to engage with the end of the portable electronic device 56. In this embodiment, the pushing component 68 is fixed to the connecting component 64, so that the pushing component 68 can move with the connecting component 64 simultaneously, but is not limited to it.

Furthermore, the fixing mechanism 58 further includes a first connector 74 and a first magnetic component 76. The first magnetic component 76 can be a L-shaped, U-shaped, square-shaped or a bar-shaped magnet, and the shape of the first magnetic component 76 depends on practical design demands. In this embodiment, the fixing mechanism 58 can further include a second magnetic component 77. That is, the fixing mechanism 58 can include two magnetic components, that is, the first magnetic component 76 and the second magnetic component 77, and the first magnetic component 76 and the second magnetic component 77 are the bar-shaped magnets. The first connector 74 is disposed on the inner side of the base 60 and for connecting the portable electronic device 56 as the portable electronic device 56 is installed on the base 60. In this embodiment, the first connector 74 can be a pogo pin connector. The first magnetic component 76 and the second magnetic component 77 are disposed on the inner side of the base 60 and installed on two sides of the first connector 74. The first magnetic component 76 and the second magnetic component 77 are for attracting an attracting component (not shown in figures) of the portable electronic device 56 as the portable electronic device 56 is installed on the base 60, so as to prevent the portable electronic device 56 from separating from the base 60. A configuration of the magnetic component is not limited to this embodiment. For example, it can dispose the square-shaped first magnetic component 76 around the first connector 74. The electronic apparatus 52 can further include a power transmission component 78 connected to the first connector 74. The power transmission component 78 is for transmitting external power to the portable electronic device 56 which is connected to the first connector 74. For example, a suite of the power transmission component 78 and the first connector 74 can be a vehicle charging module, so that the portable electronic device 56 can receive the electrical power provided by the vehicle. Moreover, the electronic apparatus 52 further includes a connection component 80 and a plurality of fixing components 82. The connection component 80 is fixed outside the base 60 for connecting the stand 54. The plurality of fixing components 82 is for fixing the connection component 80 on the base 60. In this embodiment, the electronic apparatus 52 includes two fixing components 82, and each fixing component 82 is a screw component for screwing the connection component 80 on the base 60.

A procedure for installing the portable electronic device 56 on the fixing mechanism 58 is described as follows. Please refer to FIG. 4 to FIG. 6. FIG. 4 is a sectional view illustrating that the portable electronic device 56 has not been installed on the fixing mechanism 58 according to the embodiment of the present invention. FIG. 5 is a sectional view illustrating that the portable electronic device 56 has been installed on the fixing mechanism 58 according to the embodiment of the present invention. FIG. 6 is a sectional view illustrating that the portable electronic device 56 is separated from the fixing mechanism 58 according to the embodiment of the present invention. As shown in FIG. 4, as the portable electronic device 56 has not been installed on the fixing mechanism 58, the second engaging unit 641 of the connecting component 64 is engaged with the first engaging unit 621 of the cover 62. That is, it can prevent the cover 62 from pivoting in the first pivoting direction R1 by the engagement of the first engaging unit 621 and the second engaging unit 641. Therefore, the recovering component 72 cannot drive the cover 62 to pivot at this time. As a user is desired to install the portable electronic device 56 on the fixing mechanism 58, the user only needs to put the portable electronic device 56 on the base 60 in the first direction (+X direction) by one hand. At this time, the portable electronic device 56 is to push the pushing component 68 to drive the connecting component 64 to move in the first direction (+X direction). As the portable electronic device 56 has been installed on the base 60 completely, as shown in FIG. 5, the second engaging unit 641 of the connecting component 64 is separated from the first engaging unit 621 of the cover 62. Then, the recovering component 72 drives the cover 62 to pivot in the first pivoting direction R1, so that the cover 62 can be engaged with the end of the portable electronic device 56. It is noticed that the portable electronic device 56 can selectively include a second connector 84. As the portable electronic device 56 is installed on the fixing mechanism 58, the first connector 74 is for connecting with the second connector of the portable electronic device 56, and then the power transmission component 78 can transmit the external power to the portable electronic device 56 via a connection of the first connector 74 and the second connector 84.

A protruding portion 625 is formed on the cover 62 for being forced to pivot the cover 62 in a second pivoting direction R2. As a user is desired to detach the portable electronic device 56 from the portable electronic device 56, the user can apply a force F illustrated in FIG. 5 on the protruding portion 625 of the cover 62. As the protruding portion 625 of the cover 62 is forced, the cover pivots in the second pivoting direction R2 opposite to the first pivoting direction R1 relative to the base 60, so that the cover 62 is separated from the end of the portable electronic device 56. Then, the resilient component 66 drives the pushing component 68 to move in a direction (−X direction) opposite to the first direction (+X direction) to push the portable electronic device 56, and a resilient force provided by the first connector 74 also pushes the portable electronic device 56 in the −X direction, so that the portable electronic device 56 is separated from the base 60. For example, as the first connector 74 is a pogo pin connector, the portable electronic device 56 is installed on the base 60, and the first connector 74 contacts against the second connector 84, pogo pins of the first connector 74 are pressed by pins of the second connector 84. As the portable electronic device 56 is desired to separate from the base 60, the resilient force provided by the pogo pins of the first connector 74 drives the portable electronic device 56 to separate from the base 60. In addition, the resilient component 66 drives the pushing component 68 to move in the −X direction, so that the connecting component 64 is also driven to move in the −X direction. Therefore, the connecting component 64 is engaged with the first engaging unit 621 of the cover 62 again, as shown in FIG. 4. It is noticed that the magnetic force between the first magnetic component 76, the second magnetic component 77 and the attracting component can be designed to be greater than the resilient force provided by the resilient component 66 and the first connector 74 as the cover 62 is separated from the end of the portable electronic device 56, so that the resilient force provided by the resilient component 66 and the first connector 74 cannot push the portable electronic device 56 out of the base 60. That is, the magnetic force between the first magnetic component 76 and the second magnetic component 77 and the attracting component can be slightly greater than the sum of the resilient force provided by the resilient component 66 and the first connector 74, so as to avoid that the portable electronic device 56 is pushed by the resilient force provided by the resilient component 66 and the first connector 74 to separate from the base 60 to fall on the ground in a procedure of detaching the portable electronic device 56 from the fixing mechanism 58.

In contrast to the prior art, the fixing mechanism of the present invention is to dispose the cover capable of pivoting relative to the base, the connecting component engaged with the cover and the pushing component connected to the connecting component, so that the pushing component is pushed in the first direction as the portable electronic device is to installed on the base, so as to drive the connecting component to separate from the first engaging unit of the cover. At this time, the cover can pivot relative to the base to engage with the portable electronic device, so as to fix the portable electronic device on the fixing mechanism by one hand. Therefore, it solves the conventional problem that it has to install the portable electronic device on the conventional fixing mechanism by both hands in the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fixing mechanism for fixing a portable electronic device, comprising:
a base for containing the portable electronic device;
a cover pivoted to the base, a first engaging unit being formed on the cover, and the cover being for engaging with an end of the portable electronic device after the cover pivots relative to the base in a first pivoting direction, so as to fix the portable electronic device on the base;
a connecting component disposed on the base, the connecting component comprising a second engaging unit for engaging with the first engaging unit of the cover;
at least one resilient component disposed on the base; and
a pushing component connected to the at least one resilient component and the connecting component, the pushing component being driven to move in a first direction as the portable electronic device is to be installed on the base, so as to drive the connecting component to separate from the first engaging unit of the cover, so that the cover pivots in the first pivoting direction relative to the base to engage with the end of the portable electronic device.

2. The fixing mechanism of claim 1, wherein the first engaging unit is a slot structure.

3. The fixing mechanism of claim 1, wherein the connecting component is disposed on an outer side of the base, and the at least one resilient component is disposed on an inner side of the base.

4. The fixing mechanism of claim 1, wherein after the portable electronic device is fixed on the base and the cover is forced to pivot in a second pivoting direction opposite to the first pivoting direction relative to the base, the cover is separated from the end of the portable electronic device, and the at least one resilient component drives the pushing component to push the portable electronic device, so that the portable electronic device is separated from the base.

5. The fixing mechanism of claim 4, wherein a protruding portion is formed on the cover for being forced to pivot the cover in the second pivoting direction.

6. The fixing mechanism of claim 1, wherein a constraining portion is formed on the cover, a supporting portion is formed on the base, and the constraining portion and the supporting portion are for holding the portable electronic device cooperatively.

7. The fixing mechanism of claim 1, further comprising:
at least one pivoting shaft for pivoting the cover with the base; and
at least one recovering component installed on the at least one pivoting shaft, the at least one recovering component being for driving the cover to pivot in the first pivoting direction as the connecting component is separated from the first engaging unit of the cover, so that the cover is engaged with the end of the portable electronic device.

8. The fixing mechanism of claim 1, further comprising:
a first connector disposed on the base for connecting with a second connector of the portable electronic device; and
a first magnetic component disposed on the base for attracting an attracting component of the portable electronic device, so as to prevent the portable electronic device from separating from the base.

9. The fixing mechanism of claim 8, further comprising a second magnetic component disposed on the base for attracting the attracting component of the portable electronic device with the first magnetic component cooperatively, so as to prevent the portable electronic device from separating from the base.

10. The fixing mechanism of claim 1, wherein the second engaging unit is a cylindrical engaging portion for engaging with the first engaging unit of the cover.

11. An electronic apparatus comprising:
a portable electronic device; and
a fixing mechanism for fixing the portable electronic device, the fixing mechanism comprising:
a base for containing the portable electronic device;
a cover pivoted to the base, a first engaging unit being formed on the cover, and the cover being for engaging with an end of the portable electronic device after the cover pivots relative to the base in a first pivoting direction, so as to fix the portable electronic device on the base;
a connecting component disposed on the base, the connecting component comprising a second engaging unit for engaging with the first engaging unit of the cover;
at least one resilient component disposed on the base; and
a pushing component connected to the at least one resilient component and the connecting component, the pushing component being driven to move in a first direction as the portable electronic device is to be installed on the base, so as to drive the connecting component to separate from the first engaging unit of the cover, so that the cover pivots in the first pivoting direction relative to the base to engage with the end of the portable electronic device.

12. The electronic apparatus of claim 11, wherein the first engaging unit is a slot structure.

13. The electronic apparatus of claim 11, wherein the connecting component is disposed on an outer side of the base, and the at least one resilient component is disposed on an inner side of the base.

14. The electronic apparatus of claim 11, wherein after the portable electronic device is fixed on the base and the cover is forced to pivot in a second pivoting direction opposite to the first pivoting direction relative to the base, the cover is separated from the end of the portable electronic device, and the at least one resilient component drives the pushing component to push the portable electronic device, so that the portable electronic device is separated from the base.

15. The electronic apparatus of claim 14, wherein a protruding portion is formed on the cover for being forced to pivot the cover in the second pivoting direction.

16. The electronic apparatus of claim 11, wherein a constraining portion is formed on the cover, a supporting portion is formed on the base, and the constraining portion and the supporting portion are for holding the portable electronic device cooperatively.

17. The electronic apparatus of claim 11, further comprising:
at least one pivoting shaft for pivoting the cover with the base; and
at least one recovering component installed on the at least one pivoting shaft, the at least one recovering component being for driving the cover to pivot in the first pivoting direction as the connecting component is separated from the first engaging unit of the cover, so that the cover is engaged with the end of the portable electronic device.

18. The electronic apparatus of claim 11, wherein the portable electronic device comprises a second connector, and the fixing mechanism further comprises:
a first connector disposed on the base for connecting with the second connector of the portable electronic device; and
a magnetic component disposed on the base for attracting an attracting component of the portable electronic device, so as to prevent the portable electronic device from separating from the base.

19. The electronic apparatus of claim 11, further comprising a power transmission component connected to the first connector, the power transmission component being for transmitting external power to the portable electronic device which is connected to the first connector.

20. The electronic apparatus of claim 11, further comprising:
a stand for fixing the fixing mechanism inside a vehicle; and
a connection component fixed outside the base and for connecting the stand.
